(19) United States
(12) Patent Application Publication
(10) Pub. No.: US 2026/0362597 A1
(43) Pub. Date: Nov. 12, 2026

(54) WIRING SUBSTRATE

(71) Applicant: IBIDEN CO., LTD., Gifu (JP)

(72) Inventor: Kyohei YOSHIKAWA, Gifu (JP)

(73) Assignee: IBIDEN CO., LTD., Gifu (JP)

(21) Appl. No.: 19/654,994

(22) Filed: Apr. 22, 2026

(30) Foreign Application Priority Data
May 8, 2025 (JP) 2025-078133

(51) Int. Cl. H05K 1/11; H05K 1/03; H05K 3/00

(52) U.S. Cl. CPC H05K 1/113; H05K 1/0306; H05K 3/0029; H05K 2201/09481; H05K 2201/09527; H05K 2201/09536; H05K 2201/09618

(57) ABSTRACT

A wiring substrate includes an insulating substrate, a through conductor penetrating through the substrate, an insulating layer formed on the substrate and having opening exposing surface of the through conductor, a via conductor filling the opening in the insulating layer, and an adhesion layer formed on surface of the substrate and the surface of the through conductor and between the substrate and the insulating layer. The surface of the substrate is made of glass. The via conductor includes a metal film layer and a plating film layer. The metal film layer includes a metal other than copper. The insulating layer includes organic material. The surface of the through conductor includes copper. The adhesion layer is in contact with the glass in the surface of the substrate, the copper in the surface of the through conductor, the organic material in the insulating layer, and the metal in the metal film layer.

### CROSS-REFERENCE TO RELATED APPLICATIONS

The present application is based upon and claims the benefit of priority to Japanese Patent Application No. 2025-078133, filed May 8, 2025, the entire contents of which are incorporated herein by reference.

### BACKGROUND OF THE INVENTION

### Field of the Invention

The present invention relates to a wiring substrate.

### Description of Background Art

U.S. Patent Application Publication No. 2024/0186136 describes a structure in which a surface of a substrate is coated with a polymer layer. The entire contents of this publication are incorporated herein by reference.

### SUMMARY OF THE INVENTION

According to one aspect of the present invention, a wiring substrate includes an insulating substrate, a through conductor formed in the insulating substrate such that the through conductor is penetrating through the insulating substrate, an insulating layer formed on the insulating substrate such that the insulating layer has an opening exposing a surface of the through conductor, a via conductor formed in the insulating layer such that the via conductor is filling the opening formed in the insulating layer, and an adhesion layer formed on a surface of the insulating substrate and the surface of the through conductor such that the adhesion layer is formed between the insulating substrate and the insulating layer. The surface of the insulating substrate is made of glass, the via conductor includes a metal film layer and a plating film layer such that the metal film layer includes a metal other than copper, the insulating layer includes an organic material, the surface of the through conductor includes copper, and the adhesion layer is formed in contact with the glass in the surface of the insulating substrate, the copper in the surface of the through conductor, the organic material in the insulating layer, and the metal in the metal film layer in the via conductor.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a partial enlarged cross-sectional view of the wiring substrate illustrated in FIG. 1;

FIG. 3A illustrates an example of a method for manufacturing a wiring substrate according to an embodiment of the present invention;

FIG. 3B illustrates an example of a method for manufacturing a wiring substrate according to an embodiment of the present invention;

FIG. 3C illustrates an example of a method for manufacturing a wiring substrate according to an embodiment of the present invention;

FIG. 3B illustrates an example of a method for manufacturing a wiring substrate according to an embodiment of the present invention;.

FIG. 3E illustrates an example of a method for manufacturing a wiring substrate according to an embodiment of the present invention;

FIG. 3F illustrates an example of a method for manufacturing a wiring substrate according to an embodiment of the present invention;

FIG. 3G illustrates an example of a method for manufacturing a wiring substrate according to an embodiment of the present invention; and

FIG. 3H illustrates an example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

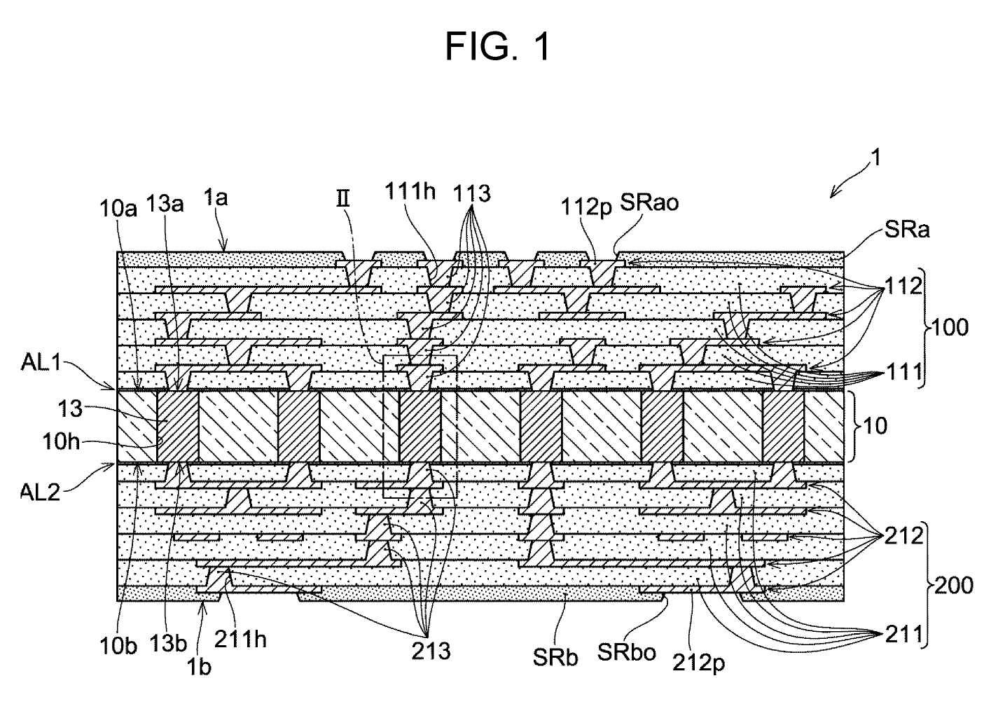

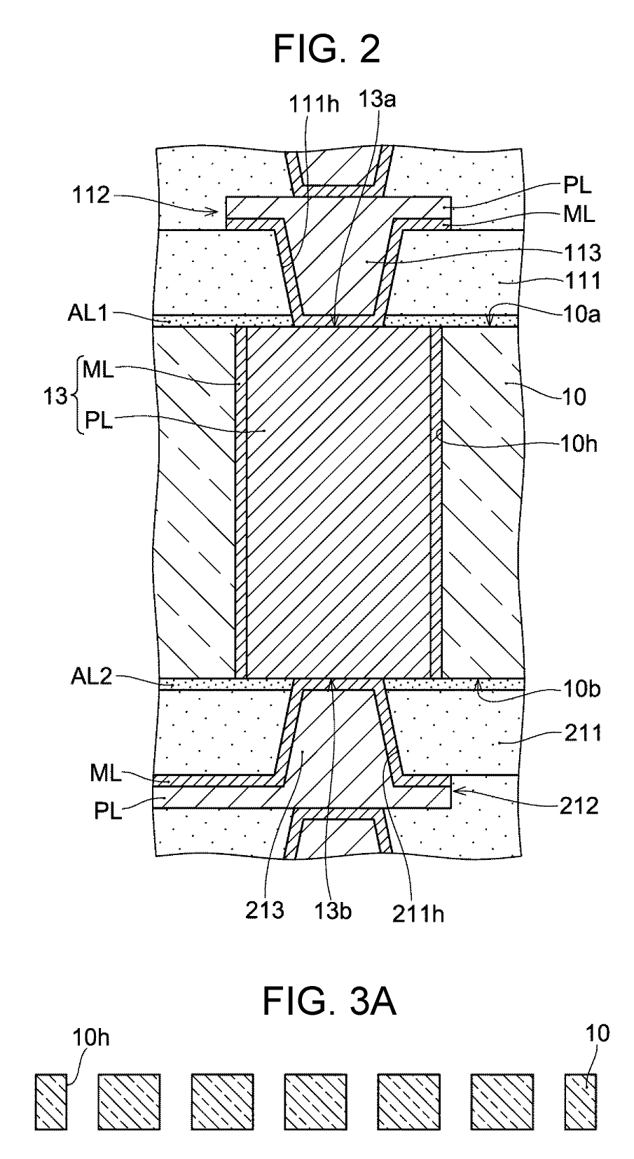

FIG. 1 illustrates a cross-sectional view of a wiring substrate 1, which is an example of a wiring substrate according to an embodiment of the present invention. FIG. 2 is a partially enlarged view of a part of the wiring substrate 1 illustrated in FIG. 1. Conductor layers and insulating layers of the wiring substrate of the embodiment are not limited to a laminated structure of the wiring substrate 1 and the number of conductor layers and insulating layers included in the wiring substrate 1.

As illustrated in FIG. 1, the wiring substrate 1 has, as outermost surfaces in its thickness direction, one outer surface (1a) and another outer surface (1b) on an opposite side with respect to the one outer surface (1a). The wiring substrate 1 includes a core substrate 10, which is an insulating substrate, and insulating layers and conductor layers alternately laminated on each of two main surfaces (one surface (10a) and another surface (10b)) facing each other in a thickness direction of the core substrate 10. Specifically, on the one surface (10a) of the core substrate 10, a first build-up part 100 having five insulating layers 111 and five conductor layers 112 alternately laminated is formed. On the other surface (10b) of the core substrate 10, a second build-up part 200 having five insulating layers 211 and five conductor layers 212 alternately laminated is formed.

In the description of the embodiment, a side farther from the core substrate 10 in the thickness direction of the wiring substrate 1 is also referred to as an “upper side” or “outer side,” or “upper” or “outer,” and a side closer to the core substrate 10 is also referred to as a “lower side” or “inner side,” or “lower” or “inner.” Further, in the description of the elements constituting the first build-up part 100 and the second build-up part 200, a surface facing away from the core substrate 10 is also referred to as an “upper surface,” and a surface facing toward the core substrate 10 is also referred to as a “lower surface.”

The wiring substrate 1 further includes connection conductors that penetrate the insulating layers and connect conductors that are adjacent to each other with an insulating layer interposed therebetween. Specifically, the core substrate 10 includes through conductor 13 that penetrate the core substrate 10 in the thickness direction. The first build-up part 100 includes via conductors 113 that penetrate the insulating layers 111 in the thickness direction. The via conductors 113 penetrating the insulating layers 111 connect the conductor layers 112 to each other, or connect the conductor layers 112 to the through conductors 13. The second build-up part 200 includes via conductors 213 that penetrate the insulating layer 211 in the thickness direction. The via conductors 213 penetrating the insulating layers 211 connect the conductor layers 212 to each other, or connect the conductor layers 212 to the through conductors 13.

The through conductors 13 connect the innermost via conductors 113 in the first build-up part 100 to the innermost via conductors 213 in the second build-up part 200. The through conductors 13 each have a first surface (13a) facing the first build-up part 100 and a second surface (13b) facing the second build-up part 200. The first surface (13a) is substantially flush with the one surface (10a) of the core substrate 10, and the second surface (13b) is substantially flush with the other surface (10b) of the core substrate 10. In a connection structure between the through conductors 13 and the via conductors (113, 213), the via conductors 113 are connected to the first surfaces (13a), and the via conductors 213 are connected to the second surfaces (13b).

In the illustrated example, a solder resist layer (SRa) is formed on the outermost conductor layer 112 and insulating layer 111 of the first build-up part 100. The solder resist layer (SRa) is provided with openings (SRao) that expose conductor pads (112p) included in the conductor layer 112. A solder resist layer (SRb) is formed on the uppermost conductor layer 212 and insulating layer 211 of the second build-up part 200. The solder resist layer (SRb) is provided with openings (SRbo) that expose conductor pads (212p) included in the conductor layer 212.

In the illustrated example, the one outer surface (1a) of the wiring substrate 1 is formed as a component mounting surface to which an external electronic component is connected, and the conductor pads (112p) constituting the one outer surface (1a) can be connected to connection pads of the external electronic component when the wiring substrate 1 is used. The other outer surface (1b) of the wiring substrate 1 can be a connection surface to be connected to, for example, an external substrate such as a motherboard of any electrical device when the wiring substrate 1 is mounted on the external substrate. When the wiring substrate 1 is used, the conductor pads (212p) constituting the other outer surface (1b) can be connected to connection pads of the external substrate.

The insulating layers (111, 211) are formed of any insulating organic material (insulating resin). As the insulating resin, a thermosetting resin or a photocurable resin is used, and specific examples include epoxy resin, polyimide resin, acrylic resin, bismaleimide triazine resin (BT resin), phenolic resin, and the like. Although not illustrated in FIG. 1, the insulating layers (111, 211) may contain a core material made of glass fiber or the like. The insulating layers (111, 211) may further contain an inorganic filler (not illustrated) made of fine particles of silica (SiO2), alumina, mullite, or the like. The solder resist layers (SRa, SRb) are formed of, for example, a photosensitive epoxy resin or polyimide resin, or the like.

The core substrate 10, which is an insulating substrate, can be formed of a glass plate. When the core substrate 10 is formed of a glass plate, the glass plate can contain any glass material such as soda-lime glass, aluminosilicate glass, or borosilicate glass. The glass plate can contain, as additives, magnesium, calcium, manganese, aluminum, lead, iron, chromium, potassium, sulfur, antimony, boron, and the like.

The via conductors 113 are formed by filling openings (111h) penetrating the insulating layers 111 with a conductor. The via conductors 213 are formed by filling openings (211h) penetrating the insulating layers 211 with a conductor. That is, the via conductors (113, 213) are formed as so-called filled vias. The through conductors 13 penetrating the core substrate 10 are formed of a conductor filling through holes (10h).

The conductor layers (112, 212), the through conductors 13, and the via conductors (113, 213) are formed using any metal such as titanium, copper, or nickel. Although illustrated as each having a single-layer structure in the drawings, the conductor layers (112, 212), the through conductors 13, and the via conductors (113, 213) can each have a multilayer structure including any of a metal foil (for example, a copper foil), a metal film layer (a sputtering film or electroless plating film containing titanium and/or copper), and a plating film layer (for example, an electrolytic copper plating film). As will be described later with reference to FIG. 2, the conductor layers (112, 212), the through conductors 13, and the via conductors (113, 213) can each have, for example, a two-layer structure including a metal film layer and a plating film layer.

Adhesion layers (AL1, AL2) are respectively formed on the surfaces of the core substrate 10 of the illustrated wiring substrate 1. The adhesion layer (AL1) is formed on the one surface (10a) of the core substrate 10, and the adhesion layer (AL1) also covers the first surfaces (13a) of the through conductors 13. The adhesion layer (AL1) improves adhesion of the core substrate 10 and the through conductors 13 to the insulating layer 111. The adhesion layer (AL1) is formed of a material that enables stronger adhesion of the core substrate 10 and the through conductors 13 to the insulating layer 111, compared to a case where the core substrate 10 and the through conductors 13 are brought into direct contact with the insulating layer 111. The adhesion layer (AL2) is formed on the other surface (10b) of the core substrate 10, and the adhesion layer (AL2) also covers the second surfaces (13b) of the through conductors 13. The adhesion layer (AL2) improves adhesion of the core substrate 10 and the through conductors 13 to the insulating layer 211. The adhesion layer (AL2) is formed of a material that enables stronger adhesion of the core substrate 10 and the through conductors 13 to the insulating layer 211, compared to a case where the core substrate 10 and the through conductors 13 are brought into direct contact with the insulating layer 211.

In the following, a structure related to the adhesion layers included in the wiring substrate of the embodiment is described in detail with reference to FIG. 2, which is an enlarged view of region (II) surrounded by a one-dot chain line in FIG. 1.

In the description with reference to FIG. 2, for ease of understanding, the insulating layer 111 in contact with the one surface (10a) of the core substrate 10 via the adhesion layer (AL1) is also referred to as the first insulating layer 111, the openings (111h) penetrating the first insulating layer 111 are also referred to as the first openings (111h), and the via conductors 113 filling the first openings (111h) are also referred to as the first via conductors 113. The adhesion layer (AL1) covering the one surface (10a) of the core substrate 10 and the first surfaces (13a) of the through conductors 13 is also referred to as the first adhesion layer (AL1). The conductor layer 112 integrally formed with the first via conductors 113 on the first insulating layer 111 is also referred to as the first conductor layer 112.

Further, the insulating layer 211 in contact with the other surface (10b) of the core substrate 10 via the adhesion layer (AL2) is also referred to as the second insulating layer 211, the openings (211h) penetrating the second insulating layer 211 are also referred to as the second openings (211h), and the via conductors 213 filling the second openings (211h) are also referred to as the second via conductors 213. The adhesion layer (AL2) covering the other surface (10b) of the core substrate 10 and the second surface (13b) of each of the through conductors 13 is also referred to as the second adhesion layer (AL2). The conductor layer 212 integrally formed with the second via conductors 213 on the second insulating layer 211 is also referred to as the second conductor layer 212.

In FIG. 2, the layers constituting the multilayer structure described above for the through conductors 13, the first conductor layer 112, the second conductor layer 212, the first via conductors 113, and the second via conductors 213 are depicted. Specifically, the through conductors 13, the first conductor layer 112, the second conductor layer 212, the first via conductors 113, and the second via conductors 213 each have a two-layer structure including a metal film layer (ML) and a plating film layer (PL).

As illustrated, the first adhesion layer (AL1), which can improve the adhesion between the core substrate 10 and the first insulating layer 111 and the adhesion between the through conductors 13 and the first insulating layer 111, is in contact with the first via conductors 113 (specifically, with the metal film layer (ML) of the first via conductors 113). That is, the first adhesion layer (AL1) is in contact with four different materials: the one surface (10a) of the core substrate 10 made of glass, the first insulating layer 111 made of an organic material, the metal film layer (ML) made of titanium, and a portion of the first surface (13a) of each of the through conductors 13 that includes a copper plating film layer. With this structure, the one surface (10a) of the core substrate 10 and the first surfaces (13a) of the through conductors 13, which are covered by the first adhesion layer (AL1), adhere to the first insulating layer 111 with sufficient strength, and the adhesion between the first via conductors 113 and the through conductors 13 is further improved. In order to further improve the adhesion between the core substrate 10 and the first insulating layer 111, the adhesion between the through conductors 13 and the first insulating layer 111, and the adhesion between the through conductors 13 and the first via conductors 113, the one surface (10a) and the first surface (13a) preferably have an arithmetic mean roughness of 1 μm or less.

Further, as illustrated, the second adhesion layer (AL2), which can improve the adhesion between the core substrate 10 and the second insulating layer 211 and the adhesion between the through conductors 13 and the second insulating layer 211, is in contact with the second via conductors 213 (specifically, with the metal film layer (ML) of the second via conductors 213). That is, the second adhesion layer (AL2) is in contact with four different materials: the other surface (10b) of the core substrate 10 made of glass, the second insulating layer 211 made of an organic material, the metal film layer (ML) made of titanium, and a portion of the second surface (13b) of each of the through conductors 13 that includes a copper plating film layer. With this structure, the other surface (10b) of the core substrate 10 and the second surfaces (13b) of the through conductors 13, which are covered by the second adhesion layer (AL2), adhere to the second insulating layer 211 with sufficient strength, and the adhesion between the second via conductors 213 and the through conductors 13 is further improved. In order to further improve the adhesion between the core substrate 10 and the second insulating layer 211, the adhesion between the through conductors 13 and the second insulating layer 211, and the adhesion between the through conductors 13 and the second via conductors 213, the other surface (10b) and the second surface (13b) preferably have an arithmetic mean roughness of 1 μm or less.

The first adhesion layer (AL1) and the second adhesion layer (AL2) are formed of a material that can adhere with good adhesion to, for example, an insulating material such as the glass constituting the core substrate 10, an organic material such as the resin constituting the insulating layers (111, 211), and an inorganic material such as the metal constituting the through conductors 13 and the via conductors (113, 213). The adhesion layers (AL1, AL2) can contain silicon nitride and can be formed, for example, by chemical vapor deposition (CVD) or physical vapor deposition (PVD). The adhesion layers (AL1, AL2) can contain, for example, silicon nitride and silicon oxide. The adhesion layers (AL1, AL2) can be, for example, sputtering films formed by sputtering. The adhesion layers (AL1, AL2) can have a thickness of, for example, 50 nm or more and 500 nm or less.

Further, the adhesion layers (AL1, AL2) may be formed of a material containing both a reactive group capable of chemically bonding to an organic material and a reactive group capable of chemically bonding to an inorganic material. In this case, examples of the material for the adhesion layers (AL1, AL2) include a silane coupling agent containing an azole silane compound such as a triazole compound.

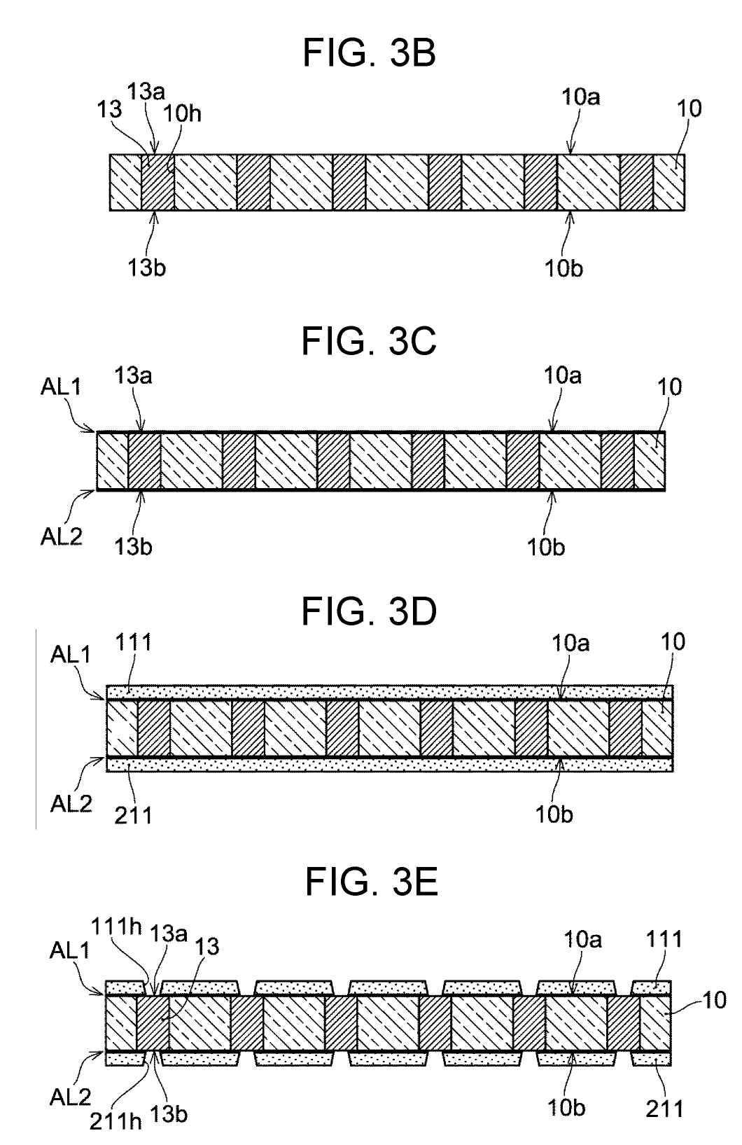

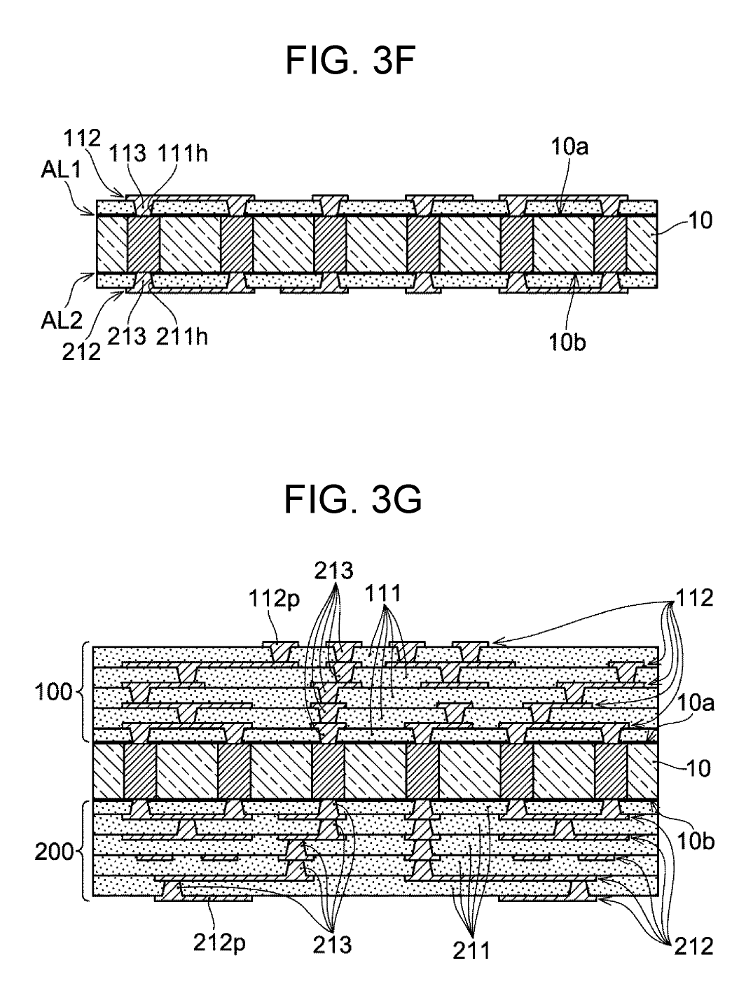

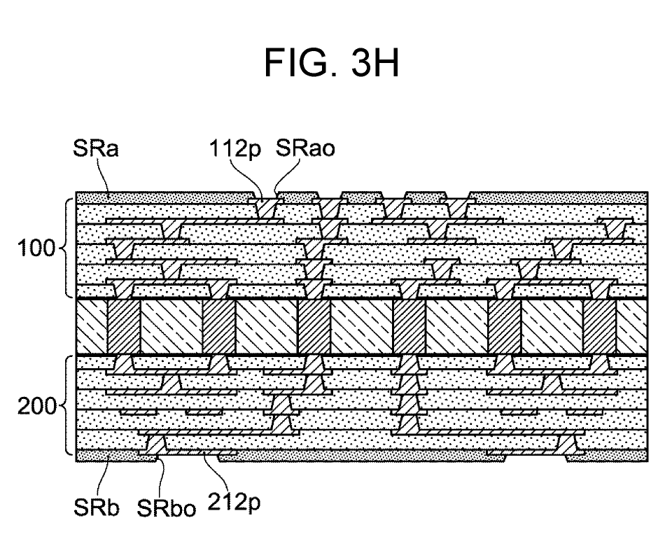

Next, an example of a method for manufacturing a wiring substrate according to an embodiment of the present invention is described with reference to FIGS. 3A-3H using a case where the wiring substrate 1 of FIG. 1 is manufactured as an example. In FIGS. 3A-3H, as in FIG. 1, the conductor layers are simplified in structure and illustrated as each having a single-layer structure.

First, as illustrated in FIG. 3A, the core substrate 10 made of glass selected from, for example, soda-lime glass, aluminosilicate glass, and borosilicate glass is prepared. The through holes (10h) are formed at positions corresponding to positions where the through conductors 13 of the core substrate 10 are to be formed (see FIG. 3B).

When the core substrate 10 is made of glass, in forming the through holes (10h), first, modified portions are formed by irradiation with laser light at the positions where the through holes (10h) are to be formed in the core substrate 10. As the laser light, a helium-neon laser, an argon ion laser, an excimer laser, various YAG lasers, and the like can be used. Subsequently, the modified portions are removed using an etching solution containing, for example, an aqueous hydrofluoric acid solution. Specifically, the modified portions are removed by immersing the core substrate (10), in which the modified portions have been formed, in an etching solution containing, for example, an aqueous hydrofluoric acid solution. As illustrated, the through holes (100h) are formed in the portions from which the modified portions have been removed.

Next, as illustrated in FIG. 3B, the through holes (10h) are filled with a conductor, and the through conductors 13 are formed. In forming the through conductors 13, first, the conductor is formed so as to completely fill the through holes (10h) and completely cover the two surfaces (the one surface (10a) and the other surface (10b)) orthogonal to the thickness direction of the core substrate 10. Subsequently, the conductor on the two surfaces of the core substrate 10 is removed by polishing, and the illustrated state is formed.

Specifically, in forming the conductor, first, a metal film layer (not illustrated) is formed on inner wall surfaces of the through holes (10h) and on the two surfaces (the one surface (10a) and the other surface (10b)) of the core substrate 10, for example, by electroless plating or sputtering. Subsequently, a plating film layer is formed on the metal film layer by electrolytic plating using the metal film layer as a power feeding layer, and the through conductors 13 having a two-layer structure (illustrated as a single layer in the drawing) including the metal film layer and the plating film layer are formed in the through holes (10h), and the two surfaces of the core substrate 10 are covered with a layer of the conductor having a two-layer structure including the metal film layer and the plating film layer.

Subsequently, the layer of the conductor covering the one surface (10a) and the other surface (10b) of the core substrate 10 is removed by polishing. As illustrated in FIG. 3B, the one surface (10a) and the other surface (10b) of the core substrate 10, and the surfaces of the through conductors 13 (the first surfaces (13a) and the second surfaces (13b)) are exposed. The one surface (10a) and the first surfaces (13a) exposed by the polishing are formed to be substantially flush with each other. The other surface (10b) and the second surfaces (13b) exposed by the polishing are formed to be substantially flush with each other. The removal of the layer of the conductor by polishing can be performed, for example, by chemical mechanical polishing (CMP).

Next, as illustrated in FIG. 3C, the adhesion layer (AL1) covering the one surface (10a) of the core substrate 10 and the first surfaces (13a) of the through conductors 13, and the adhesion layer (AL2) covering the other surface (10b) of the core substrate 10 and the second surfaces (13b) of the through conductors 13, are formed. The adhesion layer (AL1) and the adhesion layer (AL2) may be formed as silicon nitride films, for example, by chemical vapor deposition such as plasma CVD, or physical vapor deposition such as sputtering. Further, the adhesion layer (AL1) and the adhesion layer (AL2) may be formed by spraying a liquid containing a material capable of bonding to both organic and inorganic materials, such as a silane coupling agent.

Next, as illustrated in FIG. 3D, an insulating layer 111 is laminated on the one surface (10a) of the core substrate 10 and the first surfaces (13a) of the through conductors 13 with the adhesion layer (AL1) interposed between them. An insulating layer 211 is laminated on the other surface (10b) of the core substrate 10 and the second surfaces (13b) of the through conductors 13 with the adhesion layer (AL2) interposed between them. The insulating layers (111, 211) can each be formed, for example, by thermocompression bonding of a film-like thermosetting insulating resin (for example, an epoxy resin). The insulating layers (111, 211) may also each be formed, for example, by spin coating, spray coating, curtain coating, or film lamination using a photocurable resin in an uncured or semi-cured state.

Next, as illustrated in FIG. 3E, openings (111h) are formed at positions where via conductors 113 of the insulating layer 111 are to be formed (see FIG. 3F), and openings (211h) are formed at positions where via conductors 213 of the insulating layer 211 are to be formed (see FIG. 3F). When the insulating layers (111, 211) are formed of a thermosetting resin, the openings (111h, 211h) can be formed, for example, by irradiation with laser light such as CO2 laser light. In this case, simultaneously with the formation of the openings (111h, 211h), the adhesion layers (AL1, AL2) exposed at bottoms of the openings (111h, 211h) are removed, so that the first surfaces (13a) of the through conductors 13 are exposed at the bottoms of the openings (111h), and the second surfaces (13b) of the through conductors 13 are exposed at the bottoms of the openings (211h).

When the adhesion layers (AL1, AL2) are removed by laser light irradiation during the formation of the openings (111h, 211h), the adhesion layers (AL1, AL2) may deform near the bottoms of the openings (111h, 211h) due to heat generated by the laser light irradiation. Specifically, the openings (111h, 211h) near the bottoms may expand as the adhesion layers (AL1, AL2) near the bottoms of the openings (111h, 211h) contract outward from the openings (111h, 211h) in plan view.

In forming the openings (111h, 211h), when the insulating layers (111, 211) are formed of a photocurable resin, the openings (111h, 211h) can be formed by exposure and development of the insulating layers (111, 211). In this case, after the openings (111h, 211h) are formed, the adhesion layers (AL1, AL2) exposed at the bottoms of the openings (111h, 211h) can be removed, for example, by plasma etching using oxygen plasma. By removing the adhesion layers (AL1, AL2) exposed at the bottoms of the openings (111h, 211h), the first surfaces (13a) of the through conductors 13 are exposed at the bottoms of the openings (111h), and the second surfaces (13b) of the through conductors 13 are exposed at the bottoms of the openings (211h). When the insulating layers (111, 211) are formed of a photocurable resin, the adhesion layers (AL1, AL2) corresponding to the bottoms of the openings (111h, 211h) may also be removed by a dry process such as plasma etching after the formation of the adhesion layers (AL1, AL2) described with reference to FIG. 3C and before the formation of the insulating layers (111, 211) described with reference to FIG. 3D.

Next, as illustrated in FIG. 3F, on the upper side of the one surface (10a) of the core substrate 10, via conductors 113 filling the openings (111h) are formed, and a conductor layer 112 is formed. On the upper side of the other surface (10b) of the core substrate 10, via conductors 213 filling the openings (211h) are formed, and a conductor layer 212 is formed. Specifically, the via conductors (113, 213) and the conductor layers (112, 212) are formed by forming a metal film layer (not illustrated) on inner surfaces (bottom surfaces and inner wall surfaces) of the openings (111h, 211h) and on the upper surfaces of the insulating layers (111, 211) by electroless plating or sputtering, and by electrolytic plating using the metal film layer as a power feeding layer with a plating resist having appropriate openings. That is, the via conductors (113, 213) and the conductor layers (112, 212) are formed using a semi-additive process (SAP) method. By electroless plating or sputtering, the metal film layer sufficiently enters the expanded portion near the bottoms of the openings (111h, 211h) that can be formed when the openings (111h, 211h) are formed by laser light irradiation as described above with reference to FIG. 3E.

Next, as illustrated in FIG. 3G, on the upper side of the one surface (10a) of the core substrate 10, the same processes described above for forming the insulating layer 111, the conductor layer 112, and the via conductors 113 are repeated to form the first build-up part 100. Further, on the upper side of the other surface (10b) of the core substrate 10, the same processes described above for forming the insulating layer 211, the conductor layer 212, and the via conductors 213 are repeated to form the second build-up part 200. The outermost conductor layer 112 of the first build-up part 100 is formed to have patterns including the conductor pads (112p). The outermost conductor layer 212 of the second build-up part 200 is formed to have patterns including the conductor pads (212p).

Next, as illustrated in FIG. 3H, the solder resist layer (SRa) is formed on the first build-up part 100, and the solder resist layer (SRb) is formed on the second build-up part 200. The solder resist layers (SRa, SRb) are each formed, for example, by forming a resin layer containing a photosensitive epoxy resin or polyimide resin or the like and performing exposure and development using a mask having appropriate opening patterns. The solder resist layers (SRa, SRb) are formed to have the openings (SRao, SRbo) that expose the conductor pads (112p, 212p). On exposed surfaces of the conductor pads (112p, 212p), a surface protection film (not illustrated) made of Au, Ni/Au, Ni/Pd/Au, solder, or heat-resistant preflux may be formed by electroless plating, solder leveling, spray coating, or the like. The formation of the wiring substrate 1 is completed.

A wiring substrate according to an embodiment of the present invention is not limited to those having the structures illustrated in the drawings and those having the structures, shapes, and materials exemplified in the present specification. In the wiring substrate 1 described above, the first build-up part 100 and the second build-up part 200 each include five conductor layers and five insulating layers. However, the number of insulating layers and conductor layers included in the first and second build-up parts (100, 200) is not limited to this. For example, the first build-up part 100 and the second build-up part 200 may have different numbers of insulating layers and conductor layers from each other. Further, a method for manufacturing a wiring substrate according to an embodiment of the present invention is not limited to the method described with reference to FIGS. 3A-3H, and the conditions, processing order, and the like of the method may be arbitrarily modified. Further, it is also possible that a specific process may be omitted or another process may be added.

U.S. Patent Application Publication No. 2024/0186136 describes a structure in which a surface of a substrate, for example a glass substrate, is coated with a polymer layer in order to promote adhesion and to relieve stress between the substrate and a layer of metallic material and a layer of insulating material. In the layer of insulating material in contact with the substrate, via conductors are formed that connect to the layer of metallic material in contact with the substrate.

In the structure described in U.S. Patent Application Publication No. 2024/0186136, the polymer layer coating the surface of the substrate is not in contact with the via conductors. In the structure including the substrate, the layer of metallic material, the layer of insulating material, and the via conductors, it is thought that desirable adhesion between the structural elements may not be obtained.

A wiring substrate according to an embodiment of the present invention includes: an insulating substrate that has one surface and another surface on an opposite side with respect to the one surface; a through conductor that penetrates the insulating substrate from the one surface to the other surface and has a first surface exposed from the one surface; a first insulating layer that is formed on the one surface and has a first opening exposing the first surface; a first via conductor that fills the first opening; and a first adhesion layer that is provided between the one surface and the first insulating layer. The one surface is made of glass. The first via conductor includes a metal film layer and a plating film layer. The metal film layer of the first via conductor contains titanium. The first insulating layer contains an organic material. The first surface of the through conductor contains copper. The first adhesion layer is in contact with four different materials: the glass constituting the one surface; the copper constituting the first surface; the organic material constituting the first insulating layer; and the titanium constituting the metal film layer.

According to an embodiment of the present invention, a wiring substrate is provided that exhibits good adhesion between structural elements in a structure including an insulating substrate, a through conductor, an insulating layer, and a via conductor.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an insulating substrate;
a through conductor formed in the insulating substrate such that the through conductor is penetrating through the insulating substrate;
an insulating layer formed on the insulating substrate such that the insulating layer has an opening exposing a surface of the through conductor;
a via conductor formed in the insulating layer such that the via conductor is filling the opening formed in the insulating layer; and
an adhesion layer formed on a surface of the insulating substrate and the surface of the through conductor such that the adhesion layer is formed between the insulating substrate and the insulating layer,
wherein the surface of the insulating substrate is made of glass, the via conductor includes a metal film layer and a plating film layer such that the metal film layer includes a metal other than copper, the insulating layer includes an organic material, the surface of the through conductor includes copper, and the adhesion layer is formed in contact with the glass in the surface of the insulating substrate, the copper in the surface of the through conductor, the organic material in the insulating layer, and the metal in the metal film layer in the via conductor.

2. The wiring substrate according to claim 1, wherein the through conductor is formed such that the surface of the through conductor is substantially flush with the surface of the insulating substrate.

3. The wiring substrate according to claim 1, wherein the adhesion layer includes silicon nitride or a silane coupling agent.

4. The wiring substrate according to claim 1, wherein the adhesion layer has a thickness in a range of 50 nm to 500 nm.

5. The wiring substrate according to claim 1, wherein the insulating substrate and the through conductor are formed such that the surface of the insulating substrate and the surface of the through conductor have an arithmetic mean roughness of 1 μm or less.

6. The wiring substrate according to claim 1, further comprising:
a second insulating layer formed on a second surface of the insulating substrate on an opposite side with respect to the surface of insulating substrate;
a second via conductor formed in an opening formed in the second insulating layer such that the opening in the second insulating layer is exposing a second surface of the through conductor; and
a second adhesion layer formed on the second surface of the insulating substrate and the second surface of the through conductor such that the second adhesion layer is formed between the insulating substrate and the second insulating layer,
wherein the through conductor is formed such that the second surface of the through conductor is substantially flush with the second surface of the insulating substrate, and the second adhesion layer is in contact with the second surface of the insulating substrate, the second surface of the through conductor, the second insulating layer, and the second via conductor.

7. The wiring substrate according to claim 6, wherein the insulating substrate is formed such that the second surface of the insulating substrate is made of glass.

8. The wiring substrate according to claim 1, wherein the metal in the metal film layer in the via conductor includes titanium.

9. The wiring substrate according to claim 1, wherein the via conductor is formed in the insulating layer such that the via conductor is penetrating through the insulating layer and the adhesion layer.

10. The wiring substrate according to claim 2, wherein the adhesion layer includes silicon nitride or a silane coupling agent.

11. The wiring substrate according to claim 2, wherein the adhesion layer has a thickness in a range of 50 nm to 500 nm.

12. The wiring substrate according to claim 2, wherein the insulating substrate and the through conductor are formed such that the surface of the insulating substrate and the surface of the through conductor have an arithmetic mean roughness of 1 μm or less.

13. The wiring substrate according to claim 2, further comprising:
a second insulating layer formed on a second surface of the insulating substrate on an opposite side with respect to the surface of insulating substrate;
a second via conductor formed in an opening formed in the second insulating layer such that the opening in the second insulating layer is exposing a second surface of the through conductor; and
a second adhesion layer formed on the second surface of the insulating substrate and the second surface of the through conductor such that the second adhesion layer is formed between the insulating substrate and the second insulating layer,
wherein the through conductor is formed such that the second surface of the through conductor is substantially flush with the second surface of the insulating substrate, and the second adhesion layer is in contact with the second surface of the insulating substrate, the second surface of the through conductor, the second insulating layer, and the second via conductor.

14. The wiring substrate according to claim 13, wherein the insulating substrate is formed such that the second surface of the insulating substrate is made of glass.

15. The wiring substrate according to claim 2, wherein the metal in the metal film layer in the via conductor includes titanium.

16. The wiring substrate according to claim 2, wherein the via conductor is formed in the insulating layer such that the via conductor is penetrating through the insulating layer and the adhesion layer.

17. The wiring substrate according to claim 3, wherein the adhesion layer has a thickness in a range of 50 nm to 500 nm.

18. The wiring substrate according to claim 3, wherein the insulating substrate and the through conductor are formed such that the surface of the insulating substrate and the surface of the through conductor have an arithmetic mean roughness of 1 μm or less.

19. The wiring substrate according to claim 3, further comprising:
a second insulating layer formed on a second surface of the insulating substrate on an opposite side with respect to the surface of insulating substrate;
a second via conductor formed in an opening formed in the second insulating layer such that the opening in the second insulating layer is exposing a second surface of the through conductor; and
a second adhesion layer formed on the second surface of the insulating substrate and the second surface of the through conductor such that the second adhesion layer is formed between the insulating substrate and the second insulating layer,
wherein the through conductor is formed such that the second surface of the through conductor is substantially flush with the second surface of the insulating substrate, and the second adhesion layer is in contact with the second surface of the insulating substrate, the second surface of the through conductor, the second insulating layer, and the second via conductor.

20. The wiring substrate according to claim 19, wherein the insulating substrate is formed such that the second surface of the insulating substrate is made of glass.
